(19) United States
(12) Patent Application Publication
(10) Pub. No.: US 2010/0102353 A1
(43) Pub. Date: Apr. 29, 2010

(54) III-Nitride Semiconductor Light Emitting Device

(75) Inventor: Eun Hyun Park, Seongnam-si (KR)

Correspondence Address: HARNESS, DICKEY, & PIERCE, P.L.C, 7700 Bonhomme, Suite 400, ST. LOUIS, MO, 63105, US

(73) Assignee: EPIVALLEY CO., LTD., Gumi-city (KR)

(21) Appl. No.: 12/648,692

(22) Filed: Dec. 29, 2009

Related U.S. Application Data
(63) Continuation of application No. PCT/KR2009/005706, filed on Sep. 7, 2009.

(30) Foreign Application Priority Data
Oct. 15, 2008 (KR) 10-2008-0101155

(51) Int. Cl. H01L 33/00

(52) U.S. Cl. 257/98; 257/E33.067

(57) ABSTRACT

The present disclosure relates to a III-nitride semiconductor light-emitting device including a substrate, a plurality of III-nitride semiconductor layers positioned on the substrate and including an active layer which generates light by recombination of electrons and holes, and a surface scattering the light generated in the active layer, the scattering surface including a first surface which is etched and a second surface which caps the first surface.

### CROSS-REFERENCE TO RELATED APPLICATIONS

This application is a continuation of PCT Application No. PCT/KR2009/005706 filed on Sep. 7, 2009, which claims the benefit and priority to Korean Patent Application No. 10-2008-0101155, filed Oct. 15, 2008. The entire disclosures of the applications identified in this paragraph are incorporated herein by reference.

### FIELD

The present disclosure relates generally to a III-nitride semiconductor light-emitting device, and more particularly, to a III-nitride semiconductor light-emitting device with an air-void formed therein to substantially function as a scattering surface.

The III-nitride semiconductor light-emitting device means a light-emitting device such as a light-emitting diode including a compound semiconductor layer composed of Al₍ₓ₎Ga_{(y)}In_{(1-x-y)}N (0≦x≦1, 0≦y≦1, 0≦x+y≦1), and may further include a material composed of other group elements, such as SiC, SiN, SiCN and CN, and a semiconductor layer made of such materials.

### BACKGROUND

This section provides background information related to the present disclosure which is not necessarily prior art.

FIG. 1 is a view of an example of a conventional III-nitride semiconductor light-emitting device. The III-nitride semiconductor light-emitting device includes a substrate 100, a buffer layer 200 grown on the substrate 100, an n-type III-nitride semiconductor layer 300 grown on the buffer layer 200, an active layer 400 grown on the n-type III-nitride semiconductor layer 300, a p-type III-nitride semiconductor layer 500 grown on the active layer 400, a p-side electrode 600 formed on the p-type III-nitride semiconductor layer 500, a p-side bonding pad 700 formed on the p-side electrode 600, an n-side electrode 800 formed on the n-type III-nitride semiconductor layer 300 exposed by mesa-etching the p-type III-nitride semiconductor layer 500 and the active layer 400, and a protection film 900.

In the case of the substrate 100, a GaN substrate can be used as a homo-substrate. A sapphire substrate, a SiC substrate or a Si substrate can be used as a hetero-substrate. However, any type of substrate that can have a nitride semiconductor layer grown thereon can be employed. In the case that the SiC substrate is used, the n-side electrode 800 can be formed on the surface of the SiC substrate.

The nitride semiconductor layers epitaxially grown on the substrate 100 are grown usually by metal organic chemical vapor deposition (MOCVD).

The buffer layer 200 serves to overcome differences in lattice constant and thermal expansion coefficient between the hetero-substrate 100 and the nitride semiconductor layers. U.S. Pat. No. 5,122,845 describes a technique of growing an AlN buffer layer with a thickness of 100 to 500 Å on a sapphire substrate at 380 to 800° C. In addition, U.S. Pat. No. 5,290,393 describes a technique of growing an Al₍ₓ₎Ga₍₁₋ₓ₎N (0≦x<1) buffer layer with a thickness of 10 to 5000 Å on a sapphire substrate at 200 to 900° C. Moreover, U.S. Publication No. 2006/154454 describes a technique of growing a SiC buffer layer (seed layer) at 600 to 990° C., and growing an In₍ₓ₎Ga₍₁₋ₓ₎N (0<x≦1) thereon. In particular, there is provided with an undoped GaN layer with a thickness of 1 micron to several microns (μm) on the AlN buffer layer, the Al₍ₓ₎Ga₍₁₋ₓ₎N (0≦x<1) buffer layer or the SiC/In₍ₓ₎Ga₍₁₋ₓ₎N (0<x≦1) layer.

In the n-type III-nitride semiconductor layer 300, at least the n-side electrode 800 region (n-type contact layer) is doped with a dopant. In some embodiments, the n-type contact layer is made of GaN and doped with Si. U.S. Pat. No. 5,733,796 describes a technique of doping an n-type contact layer at a target doping concentration by adjusting the ratio of Si and other source materials in the mixture.

The active layer 400 generates light quanta by recombination of electrons and holes. For example, the active layer 400 contains In₍ₓ₎Ga₍₁₋ₓ₎N (0<x≦1) and has a single layer or multi-quantum well layers.

The p-type III-nitride semiconductor layer 500 is doped with an appropriate dopant such as Mg, and has p-type conductivity by an activation process. U.S. Pat. No. 5,247,533 describes a technique of activating a p-type III-nitride semiconductor layer by electron beam irradiation. Moreover, U.S. Pat. No. 5,306,662 describes a technique of activating a p-type III-nitride semiconductor layer by annealing over 400° C. U.S. Publication No. 2006/157714 describes a technique of endowing a p-type III-nitride semiconductor layer with p-type conductivity without an activation process, by using ammonia and a hydrazine-based source material together as a nitrogen precursor for growing the p-type III-nitride semiconductor layer.

The p-side electrode 600 is provided to facilitate current supply to the p-type III-nitride semiconductor layer 500. U.S. Pat. No. 5,563,422 describes a technique associated with a light-transmitting electrode composed of Ni and Au and formed almost on the entire surface of the p-type III-nitride semiconductor layer 500 and in ohmic-contact with the p-type III-nitride semiconductor layer 500. In addition, U.S. Pat. No. 6,515,306 describes a technique of forming an n-type superlattice layer on a p-type III-nitride semiconductor layer, and forming a light-transmitting electrode made of indium tin oxide (ITO) thereon.

Meanwhile, the p-side electrode 600 can be formed thick so as to not transmit but rather to reflect light toward the substrate 100. This technique is called the flip chip technique. For example, U.S. Pat. No. 6,194,743 describes a technique associated with an electrode structure including an Ag layer with a thickness over 20 nm, a diffusion barrier layer covering the Ag layer, a bonding layer containing Au and Al, and covering the diffusion barrier layer.

The p-side bonding pad 700 and the n-side electrode 800 are provided for current supply and external wire bonding. U.S. Pat. No. 5,563,422 describes a technique of forming an n-side electrode with Ti and Al.

The optional protection film 900 can be made of SiO₂.

In the meantime, the n-type III-nitride semiconductor layer 300 or the p-type III-nitride semiconductor layer 500 can be constructed as a single layer or as plural layers. Vertical light-emitting devices are introduced by separating the substrate 100 from the III-nitride semiconductor layers using a laser technique or wet etching.

A technique for forming patterns on the substrate 100 is used before growing the III-nitride semiconductor layer on the substrate 100, thereby reducing crystal defects of the III-nitride semiconductor layer or improving external quantum efficiency of the light-emitting device.

FIG. 2 is a view of an example of light-emitting devices described in U.S. Pat. Nos. 6,335,546 and 7,115,486. III-nitride semiconductor layers 200 and 300 are laterally epitaxially grown on a substrate 100 with the protrusion 110 formed thereon, thereby reducing crystal defects. As the III-nitride semiconductor layers 200 and 300 are laterally grown, cavities 120 (voids or air-voids) are formed on the substrate 100.

FIG. 3 is a view of an example of light-emitting devices described in U.S. Pat. Nos. 6,870,190 and 7,053,420. A III-nitride semiconductor layer 300 is grown on a substrate 100 with patterns formed thereon. The III-nitride semiconductor layers 300 are grown on the bottom surface and the protrusion of the patterned substrate 100, and then brought into contact with each other. The growth of the III-nitride semiconductor layer 300 is facilitated in the contact regions thereof. As such, the III-nitride semiconductor layer 300 has a flat surface. The use of the patterned substrate 100 can scatter light to improve external quantum efficiency and can reduce crystal defects to improve quality of the III-nitride semiconductor layer 300.

FIG. 4 is a view of an example of light-emitting devices described in U.S. Pat. No. 6,870,191 and U.S. Publication No. 2005/082546. A III-nitride semiconductor layer 300 is grown on a substrate 100 with the protrusion 110 formed thereon, the protrusion 110 having a circular vertical section (or non-flat top surfaces). Since the III-nitride semiconductor layer 300 is grown merely on the bottom surface of the substrate 100, it can be rapidly grown.

FIG. 5 is a view of an example of a light-emitting device described in U.S. Pat. No. 6,657,236. As a III-nitride semiconductor layer 300 is grown on a mask 130 such as SiO₂, cavities 120 are formed. The cavities 120 scatter light in the light-emitting device, thereby improving external quantum efficiency of the light-emitting device.

FIG. 6 is a view of an example of light-emitting devices described in U.S. Pat. Nos. 5,491,350 and 6,657,236. As a III-nitride semiconductor layer 300 is grown on a substrate 100 with surface patterns formed on the bottom, cavities 120 are formed in the substrate 100. The cavities 120 scatter light in the light-emitting device, thereby improving external quantum efficiency of the light-emitting device.

However, unlike the cavity 120 of FIG. 5, the cavity 120 of FIG. 6 has a small curvature on the interface with the III-nitride semiconductor layer 300. Therefore, its scattering effect is not significant.

### SUMMARY

This section provides a general summary of the disclosure, and is not a comprehensive disclosure of its full scope or all of its features.

There is provided herein a III-nitride semiconductor light-emitting device, including: a substrate; a plurality of III-nitride semiconductor layers positioned on the substrate and including an active layer which generates light by recombination of electrons and holes; and a surface scattering the light generated in the active layer, the scattering surface including a first surface which is etched and a second surface which caps the first surface.

There is also provided herein a method for fabricating a III-nitride semiconductor light-emitting device, including: a substrate; a plurality of III-nitride semiconductor layers positioned on the substrate and including an active layer which generates light by recombination of electrons and holes; and a surface scattering the light generated in the active layer, the scattering surface including a first surface which is etched and a second surface which caps the first surface.

According to a III-nitride semiconductor light-emitting device of the present disclosure, external quantum efficiency can be improved, for example, by using a cavity having a large curvature.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a view of an example of a conventional III-nitride semiconductor light-emitting device.

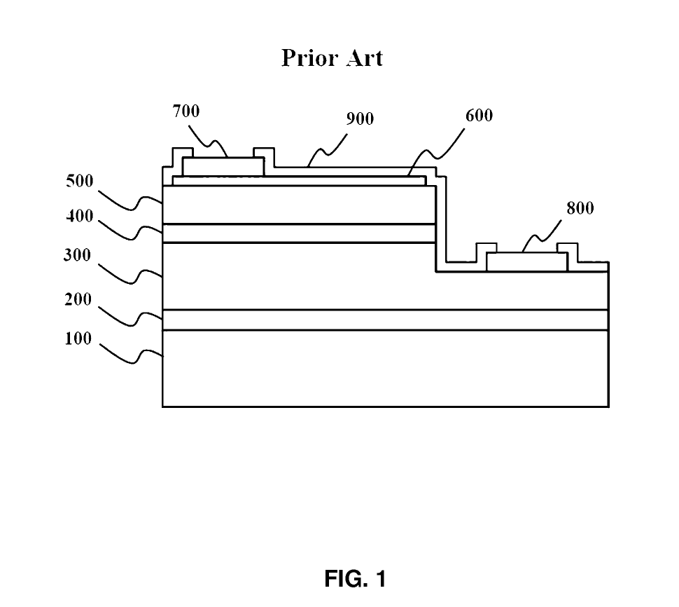

FIG. 2 is a view of an example of light-emitting devices described in U.S. Pat. Nos. 6,335,546 and 7,115,486.

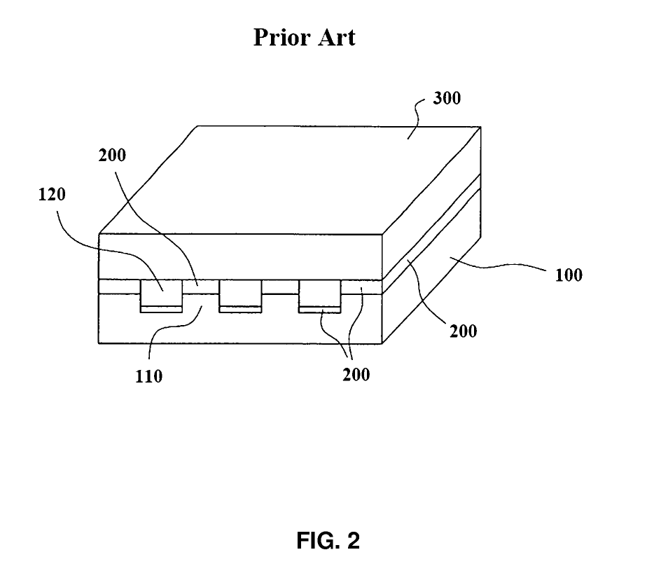

FIG. 3 is a view of an example of light-emitting devices described in U.S. Pat. Nos. 6,870,190 and 7,053,420.

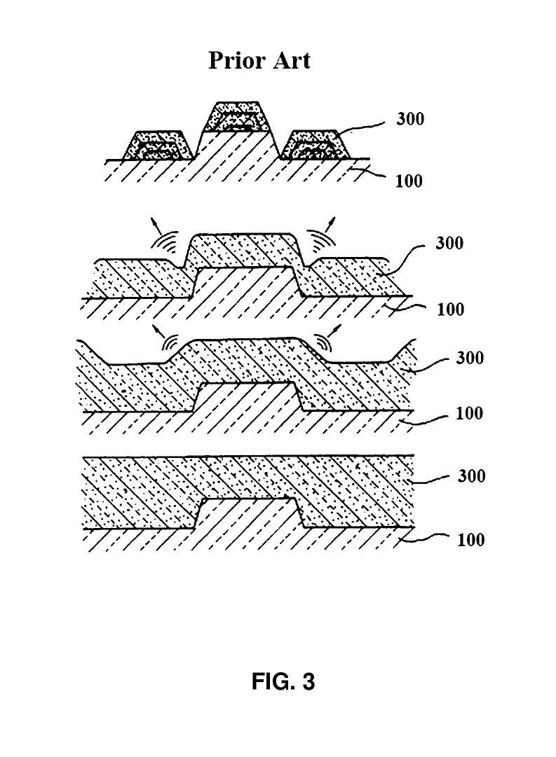

FIG. 4 is a view of an example of light-emitting devices described in U.S. Pat. No. 6,870,191 and U.S. Publication No. 2005/082546.

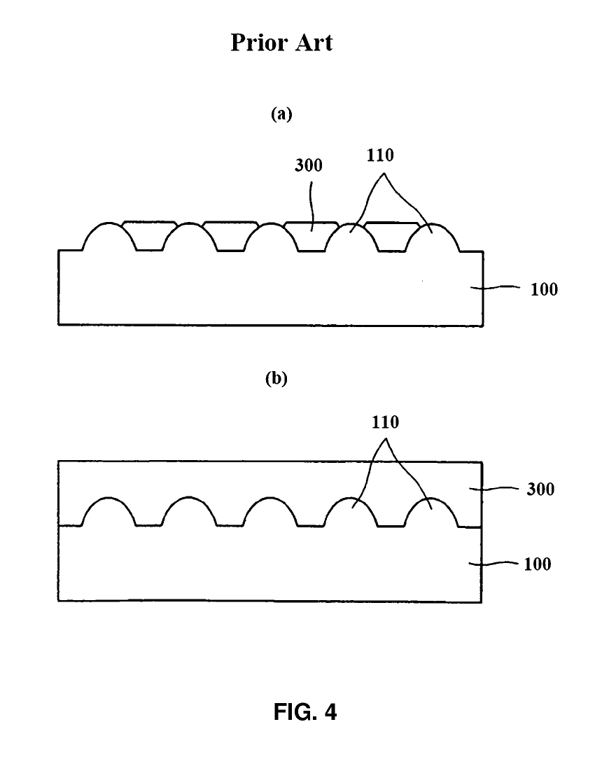

FIG. 5 is a view of an example of a light-emitting device described in U.S. Pat. No. 6,657,236.

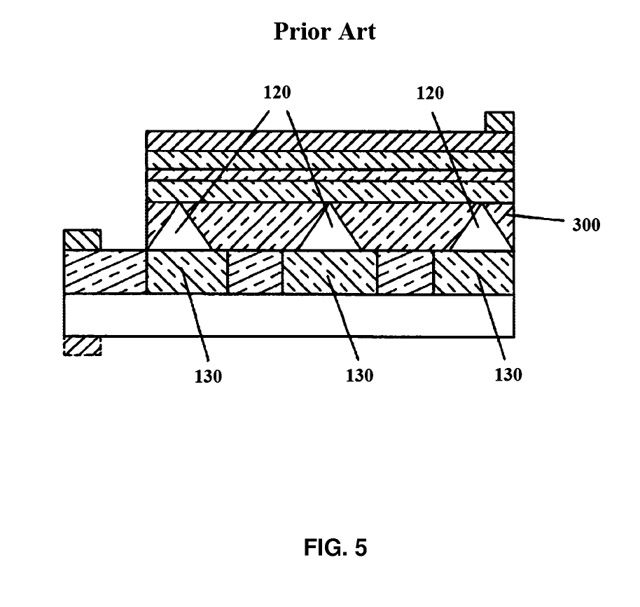

FIG. 6 is a view of an example of light-emitting devices described in U.S. Pat. Nos. 5,491,350 and 6,657,236.

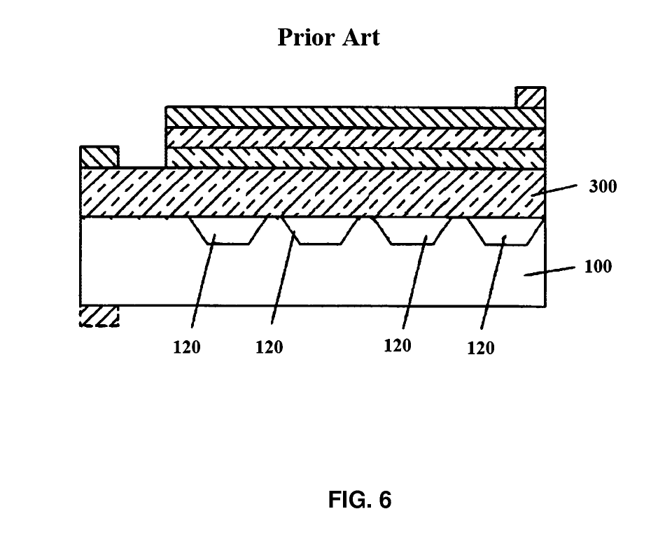

FIG. 7 is a view of an embodiment of a III-nitride semiconductor light-emitting device according to the present disclosure.

FIG. 8 is a view of an embodiment of a method for fabricating a III-nitride semiconductor light-emitting device according to the present disclosure.

FIG. 9 is a scanning electron microscope (SEM) image of a substrate obtained after the growth of a primary III-nitride semiconductor layer, when viewed from the top.

FIG. 10 is a sectional SEM image obtained after etching.

FIG. 11 is a sectional SEM image obtained after growth of a secondary III-nitride semiconductor layer.

Corresponding reference numerals indicate corresponding parts throughout the several views of the drawings.

### DETAILED DESCRIPTION

Hereinafter, the present disclosure will now be described in detail with reference to the accompanying drawings.

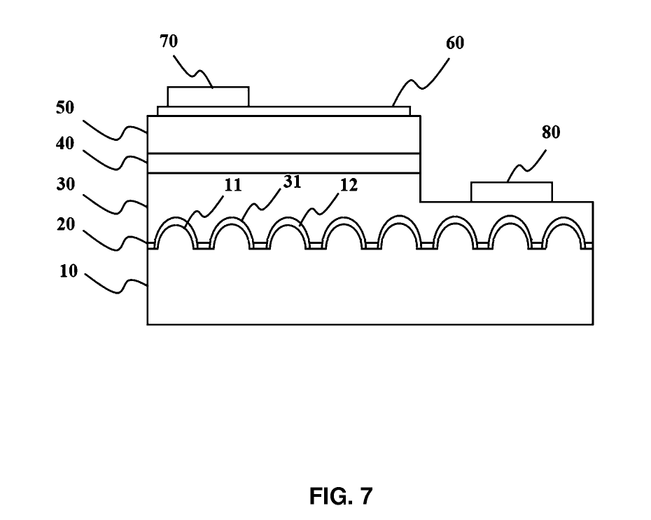

FIG. 7 is a view of an embodiment of a III-nitride semiconductor light-emitting device according to the present disclosure. The III-nitride semiconductor light-emitting device includes a substrate 10, a buffer layer 20 grown on the substrate 10, an n-type III-nitride semiconductor layer 30 grown on the buffer layer 20, an active layer 40 grown on the n-type III-nitride semiconductor layer 30, a p-type III-nitride semiconductor layer 50 grown on the active layer 40, a p-side electrode 60 formed on the p-type III-nitride semiconductor layer 50, a p-side bonding pad 70 formed on the p-side electrode 60, and an n-side electrode 80 formed on the n-type III-nitride semiconductor layer 30 exposed by mesa-etching the p-type III-nitride semiconductor layer 50 and the active layer 40. Moreover, circular protrusion 11 can be formed over the substrate 10, processed scattering surfaces 31 can be formed at the lower portion of the n-type III-nitride semiconductor layer 30, and cavities 12 can be formed between the protrusion 11 and the processed scattering surfaces 31, respectively. Therefore, according to the III-nitride semiconductor light-emitting device of the present disclosure, external quantum efficiency of the light-emitting device is improved by the processed scattering surface 31 formed between the III-nitride semiconductor layer and the cavity 12 having different refractive indexes, and by the protrusion 11 formed between the cavity 12 and the substrate 10 having different refractive indexes.

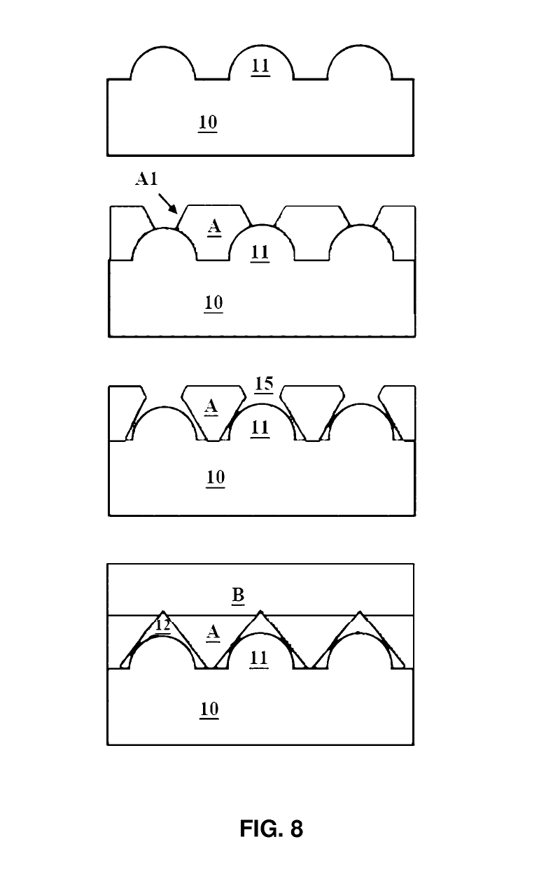

FIG. 8 is a view of an embodiment of a method for fabricating a III-nitride semiconductor light-emitting device according to the present disclosure. First, a substrate 10 with the protrusion 11 formed thereon is prepared. Here, the protrusion 11 may be formed by etching the substrate 10 or formed of a material different from the substrate 10, such as SiO₂.

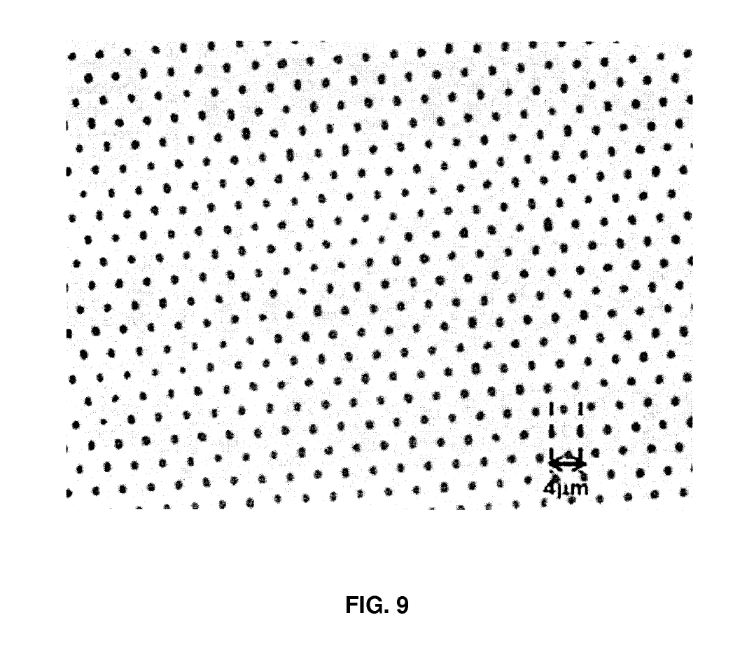

Next, a primary III-nitride semiconductor layer A is formed on the substrate 10 with the protrusion 11 formed thereon. Here, upper parts of the protrusion 11 are exposed. In this respect, protrusion 11 can be any shape. For example, protrusion 11 can have a circular or a pointed vertical section (i.e., non-flat upper parts) to prevent the primary III-nitride semiconductor layer A from being grown on the protrusion 11. In particular, when the protrusions 11 having a height of 1.2 μm and a bottom diameter of 3 μm are formed on a (0001) sapphire substrate at intervals of 1 μm, a primary III-nitride semiconductor layer A can be grown using a 30-nm buffer layer and 2-μm undoped GaN. When the undoped GaN is grown on the (0001) sapphire substrate, the primary III-nitride semiconductor layer A is formed with {10-11} surfaces A1 exposed. Accordingly, the primary III-nitride semiconductor layer A has holes formed by the {10-11} surfaces on the protrusion 11 (referring to FIG. 9).

Next, etching spaces 15 can be defined between the protrusion 11 and the primary III-nitride semiconductor layer A. The etching may be performed using, for example, a high-temperature mixed solution of phosphoric acid and sulfuric acid, a high-temperature KOH solution, high-temperature oxalic acid [(COOH)₂], or the like. The etching is rapidly performed on the interface between the protrusion 11 and the primary III-nitride semiconductor layer A having poor crystal quality, thereby defining the space 15. Here, the shape, thickness, and the like of the spaces 15 may be influenced by the etching conditions and the shape of the protrusion 11.

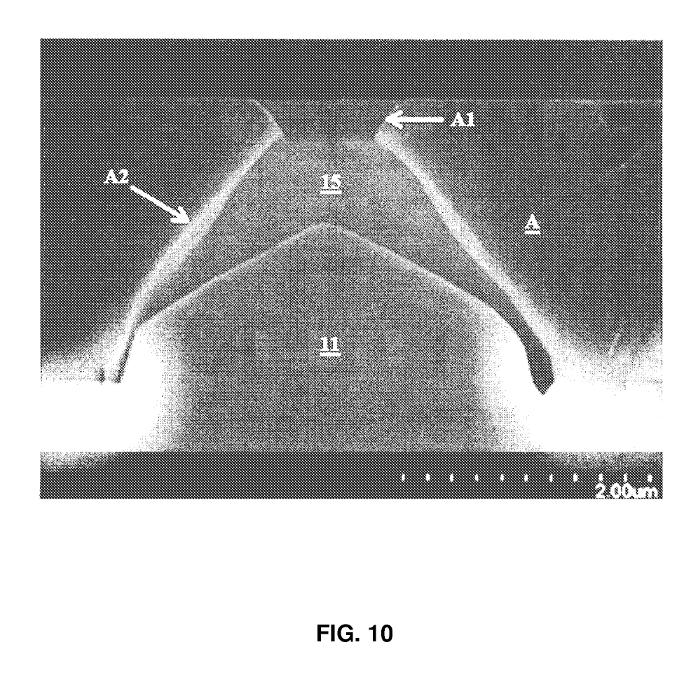

FIG. 10 is a sectional SEM image obtained after an etching. The etching was performed at 250° C. for 15 sec. using a mixed solution of phosphoric acid and sulfuric acid (3:1). The space 15 was formed between the protrusion 11 and the primary III-nitride semiconductor layer A. A {10-11} crystal surface A2 having a relatively low etching rate was exposed by etching.

Finally, a secondary III-nitride semiconductor layer B can be formed. During this process, the spaces 15 are capped by the lateral growth mode of the secondary III-nitride semiconductor layer B, thereby forming closed cavities 12. The secondary III-nitride semiconductor layer B may be formed by further growing undoped GaN (e.g., 2 μm) and then growing the n-type III-nitride semiconductor layer 30, the active layer 40, and the p-type III-nitride semiconductor layer 50 on the undoped GaN, as shown in FIG. 7.

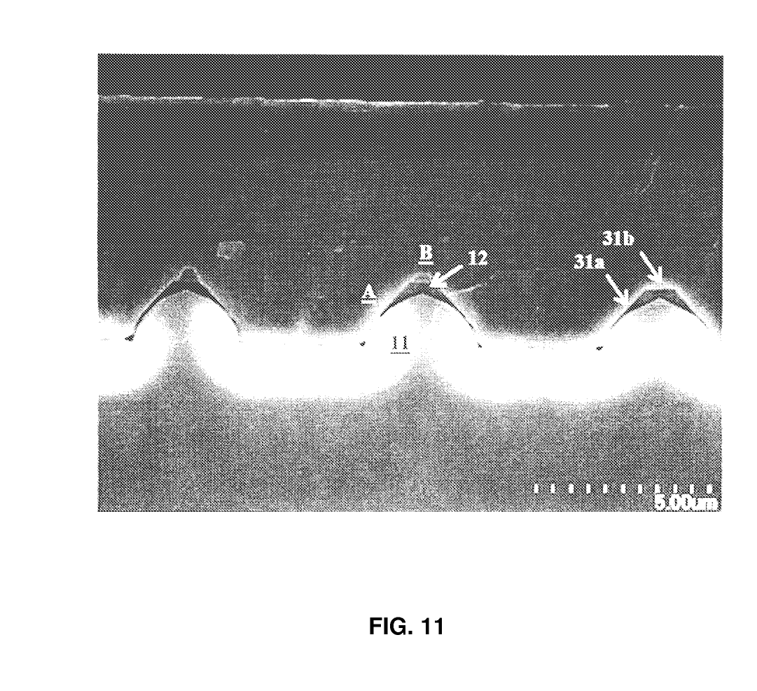

FIG. 11 is a sectional SEM image obtained after the growth of the secondary III-nitride semiconductor layer B. It can be known that the cavity 12 has been formed well, surrounded by the protrusion 11, the primary III-nitride semiconductor layer A and the secondary III-nitride semiconductor layer B. The processed scattering surface 31 (referring to FIG. 7) includes an etched surface 31a and a capping surface 31b formed by the epitaxial growth.

Hereinafter, variety embodiments of the present disclosure are explained.

(1) The III-nitride semiconductor light-emitting device comprising a protrusion disposed between a closed scattering surface and a substrate.

(2) The III-nitride semiconductor light-emitting device wherein a scattering surface is convex over the protrusion.

The III-nitride semiconductor light-emitting device further comprising a protrusion disposed below a cavity defined by an etching and formed of a material different from that of a substrate. For example, when the protrusions formed of silicon oxide, such as SiO₂, growth does not occur thereon. Therefore, although a protrusion having a flat upper part is used, the upper part of the protrusion may remain exposed during the growth of a III-nitride semiconductor layer.

(4) The III-nitride semiconductor light-emitting device further comprising a scattering surface including a cover layer formed of a III-nitride semiconductor layer.

(5) The method for fabricating a III-nitride semiconductor light-emitting device including a scattering surface formed by an etching and epitaxial growth.

The foregoing description of the embodiments has been provided for purposes of illustration and description. It is not intended to be exhaustive or to limit the invention. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the invention, and all such modifications are intended to be included within the scope of the invention.

The terminology used herein is for the purpose of describing particular example embodiments only and is not intended to be limiting. As used herein, the singular forms “a”, “an” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

What is claimed is:

1. A III-nitride semiconductor light-emitting device, comprising:
a substrate;
a plurality of III-nitride semiconductor layers positioned over the substrate and including an active layer which generates light by recombination of electrons and holes; and
a surface scattering the light generated in the active layer, the scattering surface including a first surface which is etched and a second surface which caps the first surface.

2. The III-nitride semiconductor light-emitting device of claim 1, further comprising a cavity disposed between the scattering surface and the substrate.

3. The III-nitride semiconductor light-emitting device of claim 1, further comprising a protrusion disposed between the scattering surface and the substrate.

4. The III-nitride semiconductor light-emitting device of claim 3, wherein the scattering surface has an convex shape over the protrusion.

5. The III-nitride semiconductor light-emitting device of claim 3, wherein the protrusion and the substrate are formed of sapphire.

6. The III-nitride semiconductor light-emitting device of claim 3, wherein the substrate and the protrusion are formed of different materials.

7. The III-nitride semiconductor light-emitting device of claim 1, wherein the second surface is formed by the growth of the plurality of III-nitride semiconductor layers.

8. The III-nitride semiconductor light-emitting device of claim 1, further comprising:
a cavity disposed between the scattering surface and the substrate; and
a protrusion disposed between the cavity and the substrate.

9. The III-nitride semiconductor light-emitting device of claim 8, wherein the second surface is formed by the growth of the plurality of III-nitride semiconductor layers.

10. The III-nitride semiconductor light-emitting device of claim 9, wherein the substrate is formed of sapphire.
